(19) United States
(12) Patent Application Publication
(10) Pub. No.: US 2024/0162879 A1
(43) Pub. Date: May 16, 2024

(54) Vibrator Element And Vibrator Device

(71) Applicant: SEIKO EPSON CORPORATION, Tokyo (JP)

(72) Inventors: Norihito MATSUKAWA, Shimosuwa (JP); Atsushi MATSUO, Shiojiri (JP); Kensaku ISOHATA, Minowa (JP)

(21) Appl. No.: 18/509,367

(22) Filed: Nov. 15, 2023

(30) Foreign Application Priority Data
Nov. 16, 2022 (JP) 2022-183126

(51) Int. Cl. H03H 9/02; H03H 9/05; H03H 9/10; H03H 9/19

(52) U.S. Cl. CPC H03H 9/02133; H03H 9/02102; H03H 9/0509; H03H 9/0533; H03H 9/0595; H03H 9/1021; H03H 9/19

(57) ABSTRACT

A vibrator element includes a vibrating section having a rectangular shape in a plan view and including a first principal surface, a second principal surface, and an excitation portion sandwiched by a first excitation electrode and a second excitation electrode and making a thickness-shear vibration, a coupling arm extending from a corner part of the vibrating section in a first direction, and a supporting arm having a side surface at one end part side coupled to the coupling arm and extending in a second direction crossing the first direction, wherein the supporting arm includes a first supporting electrode electrically coupled to the first excitation electrode and bonded to a container via an adhesive member, and a width of the coupling arm along the second direction is four or more times a thickness of the excitation portion along a third direction crossing the first direction and the second direction and equal to or smaller than a length from an end part of the supporting arm at the coupling arm side to the first supporting electrode along the second direction.

The present application is based on, and claims priority from JP Application Serial Number 2022-183126, filed Nov. 16, 2022, the disclosure of which is hereby incorporated by reference herein in its entirety.

### BACKGROUND

### 1. Technical Field

The present disclosure relates to a vibrator element and a vibrator device.

### 2. Related Art

JP-A-2015-186196 discloses a piezoelectric vibrator element including a vibrating section on which a pair of excitation electrodes are provided, a supporting portion extending apart from the vibrating section, and a coupling portion extending to couple one end of the supporting portion and an end part of the vibrating section, wherein extraction electrodes are respectively extracted from the pair of excitation electrodes to a joint surface of the supporting portion. According to the configuration, an influence on a vibration by supporting stress is suppressed.

In the piezoelectric vibrator element in JP-A-2015-186196, an influence on a thickness-shear vibration as a main vibration by supporting stress may be suppressed, however, no consideration is taken for the width of the coupling portion for effective isolation of a spurious vibration. Accordingly, vibration characteristics of the main vibration may be degraded by the spurious vibration.

### SUMMARY

A vibrator element according to an aspect of the present disclosure includes a vibrating section having a rectangular shape in a plan view and including a first principal surface, a second principal surface in a front-back relation with the first principal surface, and an excitation portion sandwiched by a first excitation electrode provided on the first principal surface and a second excitation electrode provided on the second principal surface and making a thickness-shear vibration, a coupling arm extending from a corner part of the vibrating section in a first direction, and a supporting arm having a side surface at one end part side coupled to the coupling arm and extending in a second direction crossing the first direction, wherein the supporting arm includes a first supporting electrode electrically coupled to the first excitation electrode and bonded to a container via an adhesive member, and a width of the coupling arm along the second direction is four or more times a thickness of the excitation portion along a third direction crossing the first direction and the second direction and equal to or smaller than a length from an end part of the supporting arm at the coupling arm side to the first supporting electrode along the second direction.

A vibrator device according to an aspect of the present disclosure includes a vibrator element, a container housing the vibrator element, and an adhesive member bonding the vibrator element and the container, wherein the vibrator element includes a vibrating section having a rectangular shape in a plan view and including a first principal surface, a second principal surface in a front-back relation with the first principal surface, and an excitation portion sandwiched by a first excitation electrode provided on the first principal surface and a second excitation electrode provided on the second principal surface and making a thickness-shear vibration, a coupling arm extending from a corner part of the vibrating section in a first direction, and a supporting arm having a side surface at one end part side coupled to the coupling arm and extending in a second direction crossing the first direction, the supporting arm includes a first supporting electrode electrically coupled to the first excitation electrode and bonded to the container via the adhesive member, and a width of the coupling arm along the second direction is four or more times a thickness of the excitation portion along a third direction crossing the first direction and the second direction and equal to or smaller than a length from an end part of the supporting arm at the coupling arm side to the first supporting electrode along the second direction.

### BRIEF DESCRIPTION OF THE DRAWINGS

FIG. 1 is a plan view showing a configuration of a vibrator device according to a first embodiment.

FIG. 2 is a sectional view along line A-A in FIG. 1.

FIG. 3 is a sectional view along line B-B in FIG. 1.

FIG. 4 shows a relationship between a width of a coupling portion and a spurious Q value.

FIG. 5 is a plan view showing a position relationship between the width of the coupling portion and a supporting electrode.

FIG. 6 is a plan view showing a configuration of a vibrator device according to a second embodiment.

FIG. 7 is a plan view showing a configuration of a vibrator device according to a third embodiment.

### DESCRIPTION OF EMBODIMENTS

### 1. First Embodiment

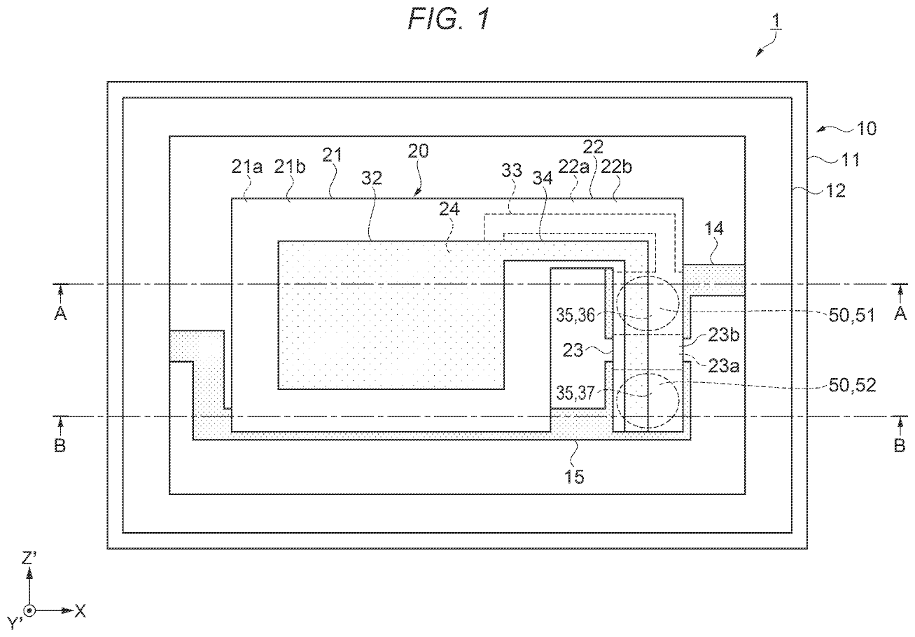

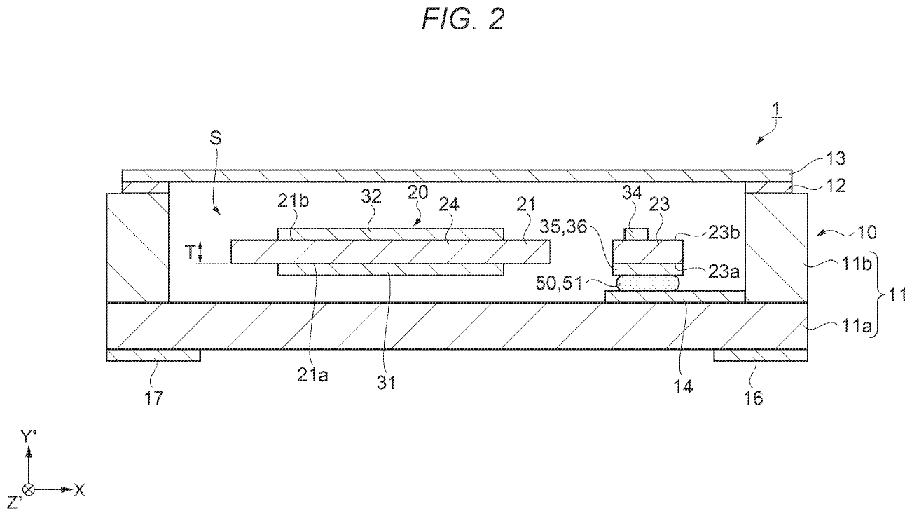

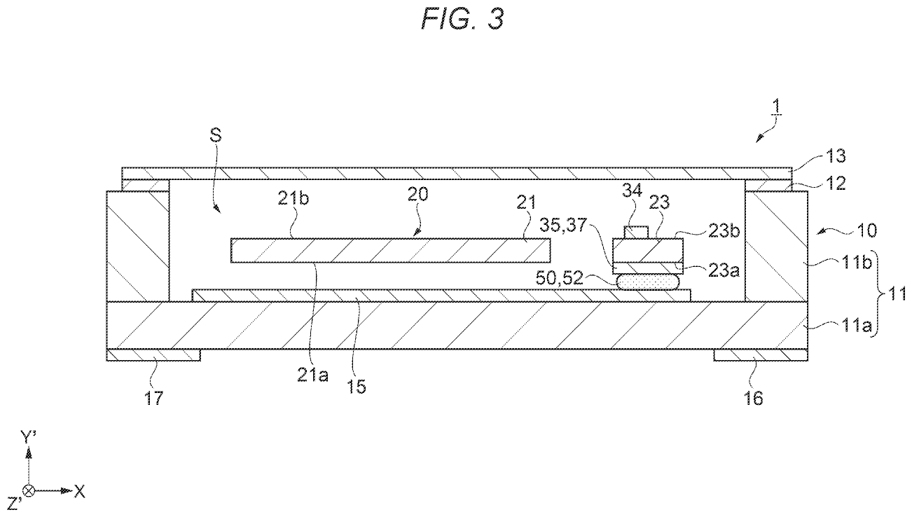

First, a vibrator device 1 according to a first embodiment will be explained with reference to FIGS. 1 to 3. In the vibrator device 1 of the embodiment, as a vibrator element 20, an AT cut quartz crystal vibrator element is taken as an example for explanation.

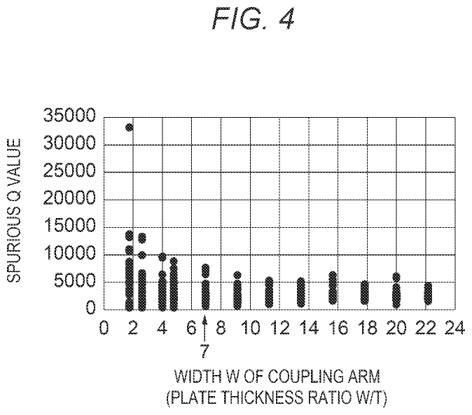

In FIG. 1, for convenience of explanation of an internal configuration of the vibrator device 1, a state without a lid 13 is shown. The AT cut quartz crystal vibrator element as the vibrator element 20 has a principal surface on an XZ-plane inclined at about 35 degrees and 15 minutes around an X-axis of X, Y, Z crystal axes from the Z-axis in the Y-axis direction. In the following description, with reference to an axial direction of the AT cut quartz crystal vibrator element, inclined new axes are used as a Y′-axis and a Z′-axis and, in the respective drawings except FIG. 4, for convenience of explanation, the X-axis, the Y′-axis and the Z′-axis orthogonal to one another are shown. Directions along the X-axis are referred to as “X directions”, directions along the Y′-axis as thickness directions of the vibrator element 20 are referred to as “Y′ directions”, and directions along the Z′-axis are referred to as “Z′ directions”. An arrow side of each axis is also referred to as “plus side” and an opposite side to the arrow is also referred to as “minus side”. The plus side in the Y′ direction is also referred to as “upper” and the minus side in the Y′ direction is also referred to as “lower”. In the specification, a first direction is the X direction or the plus X direction, a second direction crossing the first direction is the Z′ direction or the minus Z′ direction, and a third direction crossing the first direction and the second direction is the Y′ direction or the plus Y′ direction.

As shown in FIGS. 1, 2, and 3, the vibrator device 1 of the embodiment includes the vibrator element 20, a container 10 housing the vibrator element 20, and an adhesive member 50 bonding the vibrator element 20 and the container 10.

The vibrator element 20 includes a vibrating section 21 having a rectangular shape in a plan view as seen from the Y′ direction, a coupling arm 22 extending from a corner part as an end part of the vibrating section 21 in the plus X direction at the side in the plus Z′ direction to the plus X direction as the first direction, and a supporting arm 23 having a side surface at one end part side coupled to an end part of the coupling arm 22 in the plus X direction and extending in the minus Z′ direction as the second direction crossing the first direction.

The vibrating section 21 has the rectangular shape with a long side along the X direction and a short side along the Z′ direction in the plan view. Further, the vibrating section 21 has a first principal surface 21a and a second principal surface 21b having a front-back relation with the first principal surface 21a, and a first excitation electrode 31 is provided on the first principal surface 21a and a second excitation electrode 32 is provided on the second principal surface 21b. A region sandwiched by the first excitation electrode 31 and the second excitation electrode 32 is an excitation portion 24 and a thickness-shear vibration as a main vibration may be excited in the excitation portion 24.

The coupling arm 22 is a region sandwiched by the vibrating section 21 and the supporting arm 23 and has a first coupling principal surface 22a and a second coupling principal surface 22b in a front-back relation with the first coupling principal surface 22a. A first lead electrode 33 electrically coupled to the first excitation electrode 31 is provided on the first coupling principal surface 22a, and a second lead electrode 34 electrically coupled to the second excitation electrode 32 is provided on the second coupling principal surface 22b.

The supporting arm 23 has a first supporting principal surface 23a bonded to the container 10 via the adhesive member 50 and a second supporting principal surface 23b in a front-back relation with the first supporting principal surface 23a, and includes supporting electrodes 35 at an end part side opposite to the coupling arm 22. The supporting electrodes 35 include a first supporting electrode 36 and a second supporting electrode 37 placed apart from the first supporting electrode 36. On the first supporting principal surface 23a, the first supporting electrode 36 electrically coupled to the first excitation electrode 31 and the second supporting electrode 37 electrically coupled to the second excitation electrode 32 and located at the side in the minus Z′ direction of the first supporting electrode 36 are provided.

Note that the first excitation electrode 31 and the first supporting electrode 36 are electrically coupled via the first lead electrode 33 provided on the first coupling principal surface 22a of the coupling arm 22, and the second excitation electrode 32 and the second supporting electrode 37 are electrically coupled via the second lead electrode 34 provided on the second coupling principal surface 22b of the coupling arm 22 and the second supporting principal surface 23b of the supporting arm 23. Further, the second supporting electrode 37 provided on the first supporting principal surface 23a and the second lead electrode 34 provided on the second supporting principal surface 23b of the supporting arm 23 are electrically coupled via a side surface electrode (not shown) provided on a side surface of the supporting arm 23.

The adhesive member 50 is a conductive adhesive agent and includes a first adhesive agent 51 and a second adhesive agent 52 placed apart from the first adhesive agent 51. Further, the first supporting electrode 36 is bonded to the container 10 via the first adhesive agent 51 and the second supporting electrode 37 is bonded to the container 10 via the second adhesive agent 52. Note that, specifically, the first supporting electrode 36 and the second supporting electrode 37 provided on the supporting arm 23 are electrically coupled and mechanically joined to internal electrodes 14, 15 provided in the container 10 via the first adhesive agent 51 and the second adhesive agent 52, respectively. Accordingly, the vibrator element 20 is bonded into the container 10 in a cantilevered structure with the supporting arm 23 as a fixing part.

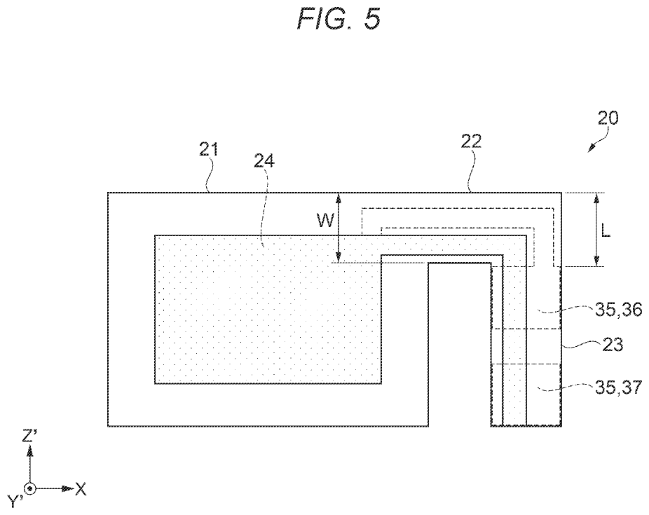

Next, an influence on vibration characteristics by a width W of the coupling arm 22 along the Z′ direction as the second direction will be explained with reference to FIGS. 4 and 5. Note that FIG. 4 shows a simulation result by a calculation of a spurious Q value for the width W of the coupling arm 22 with reference to a thickness T of the excitation portion 24 along the Y′ direction as the third direction. Further, FIG. 5 shows the vibrator element 20 with the supporting electrodes 35 etc. formed thereon.

As shown in FIG. 4, for a plate thickness ratio W/T becoming four or more times, for example, when the thickness T of the excitation portion 24 is 50 μm at a reference frequency 33 MHz, the width W of the coupling arm 22 is 200 μm and, when the width W of the coupling arm 22 is 200 μm or more, the spurious Q value tends to be 10,000 or less. Accordingly, the width W of the coupling arm 22 is set to four or more times the thickness T of the excitation portion 24 along the Y′ direction, and thereby, the spurious Q value may be 10,000 or less and degradation of the vibration characteristics of the thickness-shear vibration as the main vibration by a spurious vibration may be suppressed.

As shown in FIG. 5, the width W of the coupling arm 22 is set to be equal to or smaller than a length L from an end part of the supporting arm 23 at the coupling arm 22 side to the first supporting electrode 36 along the Z′ direction, and thereby, the distance between the excitation portion 24 and the adhesive member 50 may be made longer while the supporting strength is held and an influence on the main vibration by supporting stress such as stress when the adhesive member 50 is hardened or stress generated by a difference in coefficient of linear expansion between the vibrator element 20 and a base substrate 11 may be reduced.

Therefore, the width W of the coupling arm 22 is set to be four or more times the thickness T of the excitation portion 24 and equal to or smaller than the length L from the end part of the supporting arm 23 at the coupling arm 22 side to the first supporting electrode 36, and thereby, the spurious Q value may be 10,000 or less and the vibrator device 1 with the reduced influence on the vibration by the supporting stress may be obtained.

Note that it is preferable that the width W of the coupling arm 22 is set to seven or more times the thickness T of the excitation portion 24. The width W of the coupling arm 22 is set to seven or more times the thickness T of the excitation portion 24, and thereby, the spurious Q value may be 8,000 or less and the degradation of the vibration characteristics of the main vibration by the spurious vibration may be suppressed.

The container 10 includes the base substrate 11 formed by stacking of a first substrate 11a having a plate shape and a second substrate 11b having a frame shape and forming a housing space S, the lid 13 covering the housing space S housing the vibrator element 20, and a joint member 12 joining the base substrate 11 and the lid 13 and bringing the housing space S into an air-tight condition.

The two internal electrodes 14, 15 are provided on an upper surface of the first substrate 11a of the container 10 and two external terminals 16, 17 are provided on a lower surface of the first substrate 11a. The internal electrode 14 is electrically coupled to the first supporting electrode 36 via the first adhesive agent 51 in an end part opposite to the external terminal 16, and the internal electrode 15 is electrically coupled to the second supporting electrode 37 via the second adhesive agent 52 in an end part opposite to the external terminal 17. Note that the internal electrode 14 and the external terminal 16 are electrically coupled via a through electrode (not shown) penetrating the first substrate 11a, and the internal electrode 15 and the external terminal 17 are electrically coupled via a through electrode (not shown) penetrating the first substrate 11a.

In the embodiment, the AT cut quartz crystal vibrator element is taken as an example of the vibrator element 20 and explained, however, not limited thereto, the vibrator element may be an SC cut quartz crystal vibrator element.

As described above, in the vibrator device 1 of the embodiment, the width W of the coupling arm 22 along the Z′ direction as the second direction is four or more times the thickness T of the excitation portion 24 along the Y′ direction as the third direction and equal to or smaller than the length L from the end part of the supporting arm 23 at the coupling arm 22 side to the first supporting electrode 36 along the Z′ direction as the second direction. Therefore, the degradation of the vibration characteristics of the main vibration by the spurious vibration may be suppressed and the influence on the vibration by the supporting stress may be reduced.

### 2. Second Embodiment

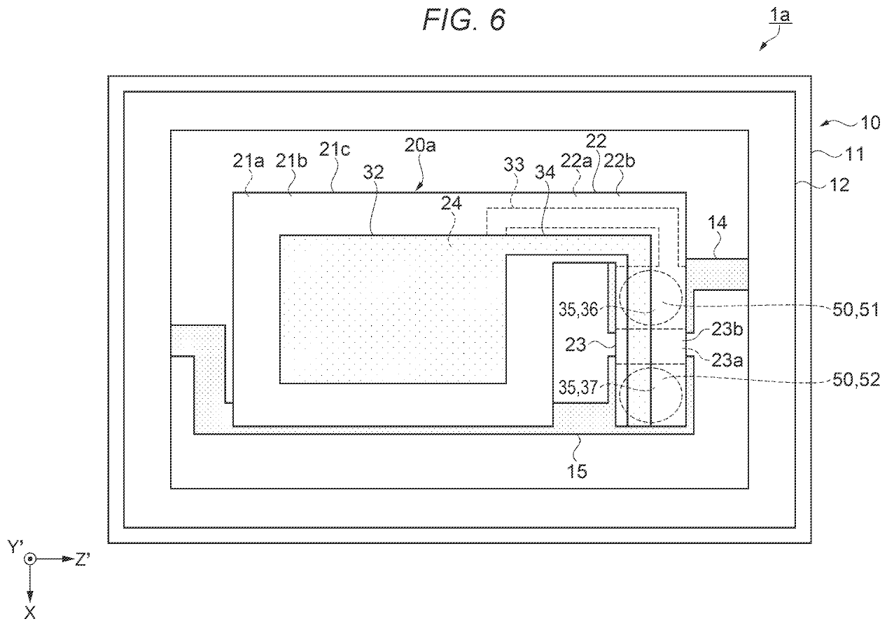

A vibrator device 1a according to a second embodiment will be explained with reference to FIG. 6.

In FIG. 6, for convenience of explanation of an internal configuration of the vibrator device 1a, a state without the lid 13 is shown.

The vibrator device 1a of the embodiment is the same as the vibrator device 1 of the first embodiment except that a short side direction of a vibrating section 21c is a first direction and a long side direction of the vibrating section 21c is a second direction. The explanation will be made with a focus on differences from the above described first embodiment and the description of the same items will be omitted.

As shown in FIG. 6, in the vibrator device 1a of the embodiment, the vibrating section 21c of a vibrator element 20a has a rectangular shape in a plan view as seen from the Y′ direction, the X direction as the first direction is the short side direction, and the Z′ direction as the second direction is the long side direction. Further, the coupling arm 22 extends from a corner part as an end part of the vibrating section 21c in the minus X direction at the side in the plus Z′ direction to the plus Z′ direction, and the supporting arm 23 extends from an end part of the coupling portion 22 in the plus Z′ direction to the plus X direction.

According to the configuration, in the vibrator element 20a having the vibrating section 21c with the long side along the Z′ direction, the same effects as the effects obtained in the first embodiment may be obtained.

### 3. Third Embodiment

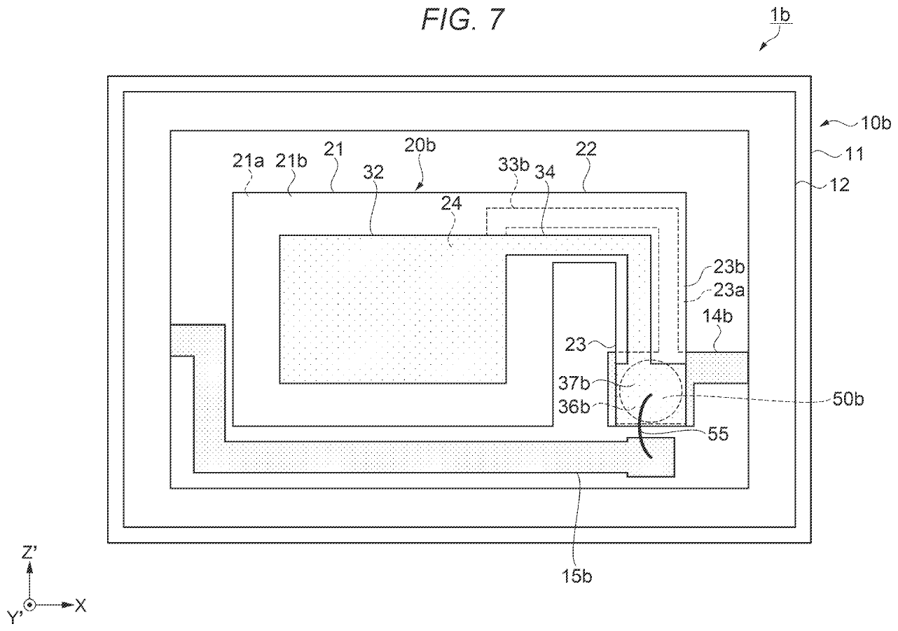

A vibrator device 1b according to a third embodiment will be explained with reference to FIG. 7.

In FIG. 7, for convenience of explanation of an internal configuration of the vibrator device 1b, a state without the lid 13 is shown.

The vibrator device 1b of the embodiment is the same as the vibrator device 1 of the first embodiment except that only one adhesive member 50b is provided, a second supporting electrode 37b is placed on the second supporting principal surface 23b, the second supporting electrode 37b is electrically coupled to a container 10b via a bonding wire 55, and a position of an internal electrode 14b and a shape of an internal electrode 15b are different. The explanation will be made with a focus on differences from the above described first embodiment and the description of the same items will be omitted.

As shown in FIG. 7, in the vibrator device 1b of the embodiment, the second supporting electrode 37b is placed on the second supporting principal surface 23b and the second supporting electrode 37b is electrically coupled to the internal electrode 15b of the container 10b via the bonding wire 55.

The supporting arm 23 is joined to the container 10b at the first supporting principal surface 23a side via the adhesive member 50b as a conductive adhesive agent. More specifically, a first supporting electrode 36b provided on the first supporting principal surface 23a is electrically coupled to the internal electrode 14b provided in the container 10b via the adhesive member 50b. Therefore, the distance from the vibrating section 21 to the adhesive member 50b may be sufficiently separated, and thereby, the influence by spurious may be reduced and the influence by the supporting stress may be further suppressed.

According to the configuration, the same effects as the effects obtained in the first embodiment may be obtained. Note that, in the embodiment, the supporting arm 23 is bonded to the container 10b by the one adhesive member 50b, however, in order to increase the supporting strength, the supporting arm 23 may be bonded to the container 10b by two adhesive members 50b like the first embodiment.

What is claimed is:

1. A vibrator element comprising:
a vibrating section having a rectangular shape in a plan view and including a first principal surface, a second principal surface in a front-back relation with the first principal surface, and an excitation portion sandwiched by a first excitation electrode provided on the first principal surface and a second excitation electrode provided on the second principal surface and making a thickness-shear vibration;
a coupling arm extending from a corner part of the vibrating section in a first direction; and
a supporting arm whose side surface at one end part is coupled to the coupling arm and extending in a second direction crossing the first direction, wherein
the supporting arm includes a first supporting electrode electrically coupled to the first excitation electrode and bonded to a container via an adhesive member, and
a width of the coupling arm along the second direction is four or more times a thickness of the excitation portion along a third direction crossing the first direction and the second direction and equal to or smaller than a length from an end part of the supporting arm at the coupling arm side to the first supporting electrode along the second direction.

2. The vibrator element according to claim 1, wherein
the supporting arm further includes a second supporting electrode electrically coupled to the second excitation electrode and located at a side in the second direction of the first supporting electrode.

3. The vibrator element according to claim 1, wherein
the width of the coupling arm along the second direction is seven or more times the thickness of the excitation portion along the third direction.

4. The vibrator element according to claim 1, wherein
the first direction is a long side direction of the vibrating section and the second direction is a short side direction of the vibrating section.

5. The vibrator element according to claim 1, wherein
the first direction is a short side direction of the vibrating section and the second direction is a long side direction of the vibrating section.

6. A vibrator device comprising:
a vibrator element;
a container housing the vibrator element; and
an adhesive member bonding the vibrator element and the container, wherein
the vibrator element includes
a vibrating section having a rectangular shape in a plan view and including a first principal surface, a second principal surface in a front-back relation with the first principal surface, and an excitation portion sandwiched by a first excitation electrode provided on the first principal surface and a second excitation electrode provided on the second principal surface and making a thickness-shear vibration,
a coupling arm extending from a corner part of the vibrating section in a first direction, and
a supporting arm having a side surface at one end part side coupled to the coupling arm and extending in a second direction crossing the first direction,
the supporting arm includes a first supporting electrode electrically coupled to the first excitation electrode and bonded to the container via the adhesive member, and
a width of the coupling arm along the second direction is four or more times a thickness of the excitation portion along a third direction crossing the first direction and the second direction and equal to or smaller than a length from an end part of the supporting arm at the coupling arm side to the first supporting electrode along the second direction.

7. The vibrator device according to claim 6, wherein
the supporting arm includes a first supporting principal surface bonded to the container via the adhesive member, a second supporting principal surface in a front-back relation with the first supporting principal surface, and a second supporting electrode electrically coupled to the second excitation electrode and located at a side in the second direction of the first supporting electrode,
the first supporting electrode and the second supporting electrode are provided on the first supporting principal surface,
the adhesive member includes a first adhesive agent and a second adhesive agent placed apart from the first adhesive agent,
the first adhesive agent and the second adhesive agent are conductive adhesive agents,
the first supporting electrode is bonded to the container via the first adhesive agent, and
the second supporting electrode is bonded to the container via the second adhesive agent.

8. The vibrator device according to claim 6, wherein
the supporting arm includes a first supporting principal surface bonded to the container via the adhesive member, a second supporting principal surface in a front-back relation with the first supporting principal surface, and a second supporting electrode electrically coupled to the second excitation electrode,
the first supporting electrode is provided on the first supporting principal surface,
the second supporting electrode is provided on the second supporting principal surface,
the adhesive member is a conductive adhesive agent,
the first supporting electrode is electrically coupled to the container via the adhesive member, and
the second supporting electrode is electrically coupled to the container via a bonding wire.
